(19) United States
(12) Patent Application Publication
(10) Pub. No.: US 2015/0068581 A1
(43) Pub. Date: Mar. 12, 2015

(54) Fabrication Method for Multi-junction Solar Cells

(71) Applicant: XIAMEN SANAN OPTOELECTRONICS TECHNOLOGY CO., LTD., Xiamen (CN)

(72) Inventors: JINGFENG BI, Xiamen (CN); GUIJIANG LIN, Xiamen (CN); JIANQING LIU, Xiamen (CN); JIE DING, Xiamen (CN)

(73) Assignee: XIAMEN SANAN OPTOELECTRONICS TECHNOLOGY CO., LTD., Xiamen (CN)

(21) Appl. No.: 14/541,079

(22) Filed: Nov. 13, 2014

Related U.S. Application Data
(63) Continuation of application No. PCT/CN2013/078965, filed on Jul. 8, 2013.

(30) Foreign Application Priority Data
Jul. 19, 2012 (CN) 201210249856.3

(51) Int. Cl. H01L 31/0725; H01L 31/18; C30B 29/40; C30B 23/02; C30B 25/02; C30B 25/18; H01L 31/0735; C30B 23/06

(52) U.S. Cl. CPC H01L 31/0725; H01L 31/0735; H01L 31/1844; H01L 31/1852; C30B 23/066; C30B 23/025; C30B 25/02; C30B 25/186; C30B 29/40
USPC 136/244; 117/92; 118/719

(57) ABSTRACT

A fabrication method for high-efficiency multi junction solar cells, including: providing a Ge substrate for semiconductor epitaxial growth; growing an emitter region over the Ge substrate (as the base) to form a first subcell with a first band gap; forming a second subcell with a second band gap larger than the first band gap and lattice matched with the first subcell over the first subcell via MBE; forming a third subcell with a third band gap larger than the second band gap and lattice matched with the first and second subcells over the second subcell via MOCVD; and forming a fourth subcell with a fourth band gap larger than the third band gap and lattice matched with the first, second and third subcells over the third subcell via MOCVD.

### CROSS-REFERENCE TO RELATED APPLICATIONS

The present application is a continuation of, and claims priority to, PCT/CN2013/078965 filed on Jul. 8, 2013, which claims priority to Chinese Patent Application No. CN 201210249856.3 filed on Jul. 19, 2012. The disclosures of these applications are hereby incorporated by reference in their entirety.

### BACKGROUND

The present disclosure relates to a multi junction solar cell, which pertains to the semiconductor material field.

Solar cell, as a new and practical way of generating energy, has drawn more attentions in recent years. It is a semiconductor device that converts solar energy into electric energy with photovoltaic effect, and has become one of the most effective approaches for green energy for reducing dependence on coal, petroleum and natural gas. Amongst all new energies, solar cell is one of the most ideal renewable energy sources, its full and effective development has become an important energy strategic policy of sustainable development for all countries in the world. In recent years, multi junction component solar cells, which represent the third-generation photovoltaic power technology, has attracted more attentions due to their high photoelectric conversion efficiency.

GaInP/GaAs/Ge three junction solar cells can achieve as high as 41.8% photoelectric conversion efficiency under concentrated conditions. However, mismatching of short-circuit currents of top cells between InGaP and GaAs, resulting from the Ge bottom cell absorbing too many low-energy photon, tends to prevent the traditional GaInP/GaAs/Ge three junction solar cell from being the most optimized combination in terms of efficiency for. Ideally, current matching is available in the three junction cell if Ge is replaced by material of 1 eV energy gap. The alternative 1 eV In_{0.3}Ga_{0.7}As, despite of a 2.14% lattice mismatch with GaAs, has relatively high cost due to complex process after inverted growth.

### SUMMARY

According to a first aspect of the present disclosure, a fabrication method for high effective multi junction solar cells is provided, comprising (1) providing a Ge substrate for semiconductor epitaxial growth; (2) growing an emitter region on the Ge substrate (as the base) to form a first subcell with a first band gap; (3) forming a second subcell with a second band gap larger than the first band gap and matching lattice with the first subcell over the first subcell via MBE; (4) forming a third subcell with a third band gap larger than the second band gap and matching lattice with the first and second subcells over the second subcell via MOCVD; and (5) forming a fourth subcell with a fourth band gap larger than the third band gap and matching lattice constants with the first, second and third subcells over the third subcell via MOCVD.

According to a second aspect of the present disclosure, an epitaxial growth system of solar cell, comprising an MOCVD reaction chamber, an MBE reaction chamber and a pre-processing chamber, wherein, the MOCVD reaction chamber and the MBE reaction chamber share the pre-processing chamber and are mutually connected via a channel. A transmission device is provided inside the channel.

Through a designed combination of MOCVD and MBE crystal growth methods, an in-situ growth of required solar cell structure is available in different growing chambers, thus guaranteeing sample surface cleanliness and improving lattice quality.

The accompanying drawings, which are included to provide a further understanding of the invention and constitute a part of this specification, together with the embodiments, are therefore to be considered in all respects as illustrative and not restrictive. In addition, the drawings are merely illustrative, which are not drawn to scale.

### BRIEF DESCRIPTION OF THE DRAWINGS

FIG. 1 is a diagram illustrating the relationship between 1 eV GaInNAsSb band gap and lattice constant.

FIG. 2 is a schematic diagram of an epitaxial growth device of solar cells according to this disclosure.

FIG. 3 is a distribution diagram of band gaps of a high effective five-junction solar cell according to this disclosure.

FIG. 4 is a process flow diagram disclosed in Embodiment 2.

FIG. 5 is a process flow diagram for epitaxial growth of a second subcell according to this disclosure.

FIG. 6 is a structure diagram of a multi junction solar cell disclosed in Embodiment 2.

FIG. 7 is a process flow diagram disclosed in Embodiment 3.

FIG. 8 is a structure diagram of a multi junction solar cell disclosed in Embodiment 3.

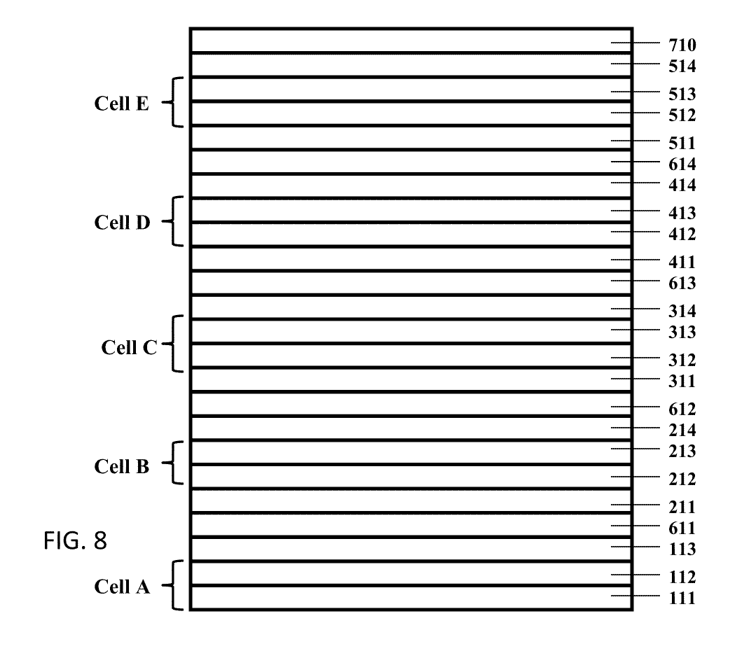

### IN THE DRAWINGS

100, 110: first subcell; 101, 111: p-type Ge substrate; 102, 112: first subcell emitter region; 103, 113: first subcell window layer; 200, 210: second subcell; 201, 211: second subcell back surface field layer; 202, 212: second subcell base; 203, 213: second subcell emitter region; 204, 214: second subcell window layer; 300, 310: third subcell; 301, 311: third subcell back surface field layer; 302, 312: third subcell base; 303, 313: third subcell emitter region; 304, 314: third subcell window layer; 400, 410: fourth subcell; 401, 411: fourth subcell back surface field layer; 402, 412: fourth subcell base; 403, 413: fourth subcell emitter region; 404, 414: fourth subcell window layer; 510: fifth subcell; 511: fifth subcell back surface field layer; 512: fifth subcell base; 513: fifth subcell emitter region; 514: fifth subcell window layer; 611: tunnel junction between the first and second subcells; 612: tunnel junction between the second and third subcells; 613: tunnel junction between the third and fourth subcells; 614: tunnel junction between the fourth and fifth subcells; 700, 710: cap layer; 800: device system; 810: MOCVD reaction chamber; 820: MEB reaction chamber; 830: pre-processing chamber; 840: vacuum channel.

### DETAILED DESCRIPTION

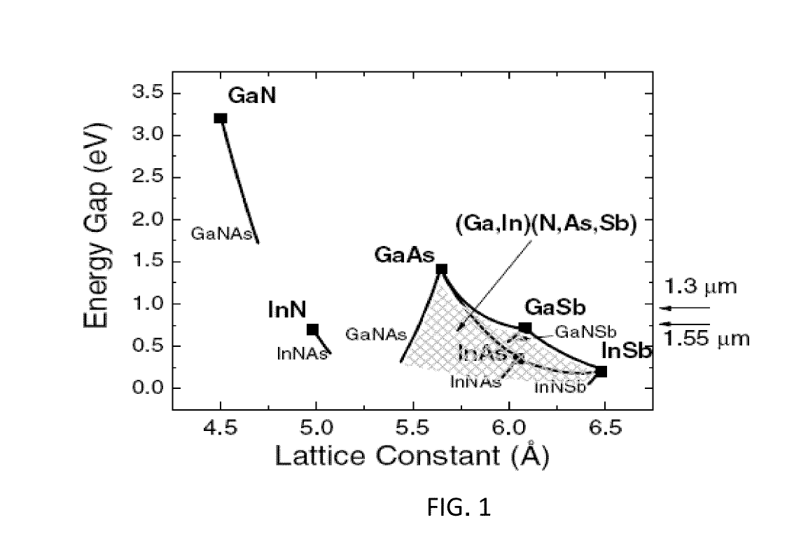

FIG. 1 is a relational graph of 1 eV GaInNAsSb band gap and lattice constant. According to the figure, a 1 eV GaInNAs(Sb) subcell is inserted into the traditional GaInP/GaAs/Ge three junction solar cell to form a four-junction solar cell to achieve cell current matching. The lattice matching between GaInNAs(Sb) and GaAs also increases photoelectric conversion efficiency of the solar cell.

In a conventional epitaxial growth process, a high-quality lattice GaInNAs(Sb) material is obtained through MBE growth method. However, the MBE epitaxial growth method, despite its low growth rate, requires high vacuum and low temperature condition, which is not applicable for most material (e.g., S, P). To solve the above problems, the embodiments disclose an epitaxial growth system for multi junction solar cells that integrates the MOCVD system and the MBE system (connected by a vacuum channel) in one pre-processing chamber. A transmission device is provided in the vacuum channel for epitaxial wafer transmission between the MOCVD system and the MBE system during epitaxial growth.

According to some embodiments described below, an epitaxial growth system is provided to fabricate high-effective multi junction solar cells.

A four junction solar cell is prepared by the epitaxial growth system according to some embodiments, comprising:

On a p-type Ge substrate, growing an n-type GaAs as the emitter region in the MBE growing chamber and the Ge substrate serves as a base, constituting a first subcell with a first band gap (0.65-0.70 eV).

Growing a GaInNAs(Sb) second subcell with a second band gap (0.95-1.05 eV) larger than the first band gap and matching lattice with the first subcell over the first subcell via MBE epitaxial growth.

Transmitting the first and second subcells to the MOCVD growing chamber through the transmission device for further growth.

Growing a third subcell with a third band gap (1.35-1.45 eV) larger than the second band gap and matching lattice with the first and second subcells over the second subcell via MOCVD.

Growing a fourth subcell with a fourth band gap (1.86-1.95 eV) larger than the third band gap and matching lattice with the first, second and third subcells over the third subcell via MOCVD.

Form a high-doped cap layer over the fourth subcell.

A fifth junction solar cell is prepared by the epitaxial growth system according to some embodiments, comprising:

On a p-type Ge substrate, growing an n-type GaAs as the emitter region in the MBE growing chamber and the Ge substrate serves as a base, constituting a first subcell with a first band gap (0.67-0.70 eV).

Growing a GaInNAs(Sb) second subcell with a second band gap (0.95-1.05 eV) larger than the first band gap and matching lattice with the first subcell over the first subcell via MBE epitaxial growth.

Transmitting the first and second subcells to the MOCVD growing chamber through the transmission device for further growth.

Growing a third subcell with a third band gap (1.40-1.42 eV) larger than the second band gap and matching lattice with the first and second subcells over the second subcell via MOCVD.

Growing a fourth subcell with a fourth band gap (1.60-1.70 eV) larger than the third band gap and matching lattice with the first, second and third subcells over the third subcell via MOCVD.

Growing an AlₓGa_{y}In_{1-x-y}P fifth subcell with a fifth band gap (1.90-2.10 eV) larger than the fourth band gap and matching lattice with the first, second, third and fourth subcells over the fourth subcell via MOCVD.

Form a highly-doped cap layer over the fifth subcell.

More specially, in some embodiments, the growth method for the GaInNAs(Sb) second subcell comprises: forming a back surface field layer via MOCVD over the first subcell; forming a GaInNAs(Sb) base and an emitter region on the back surface field layer via MBE; and forming a window layer over the emitter region via MOCVD, thus constituting a second subcell.

Refer to Embodiments 1-3 for more details.

### Embodiment 1

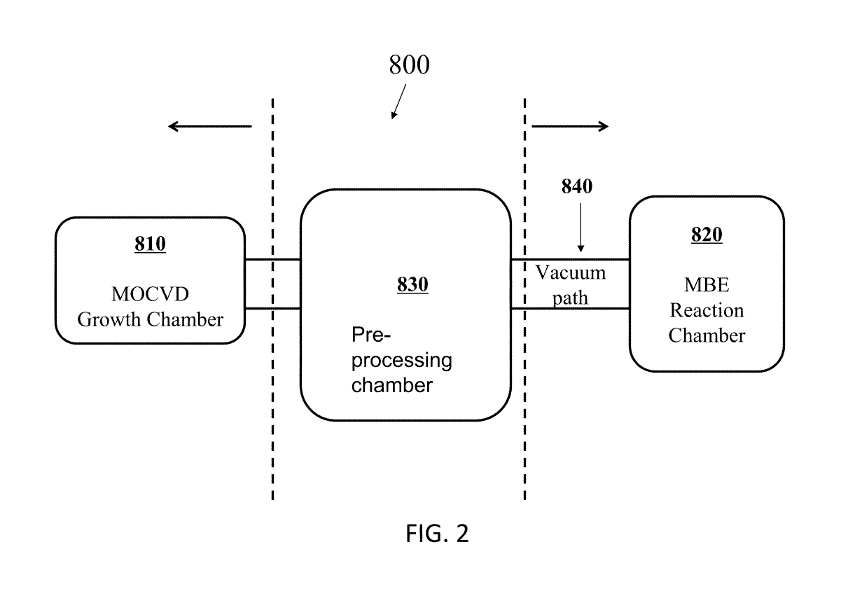

FIG. 2 discloses an epitaxial growth system 800 for multi junction solar cells. The epitaxial growth system 800 has an MOCVD system, an MBE system and a pre-processing chamber 830, wherein, the MOCVD reaction chamber 810 and the MBE reaction chamber 820 share the pre-processing chamber 830. The vacuum channel 840 connects the MOCVD reaction chamber 810 and the MBE reaction chamber 820 with vacuum degree maintained below 1×10⁻⁶ Pa. A transmission device is provided in the vacuum channel to transmit the epitaxial wafer between the MOCVD system and the MBE system during epitaxial growth.

In the epitaxial growth system, the MOCVD reaction chamber 810 and the MBE reaction chamber 820 are arranged in a same pre-processing chamber. A transmission device is provided to realize conversion between the MOCVD growth and the MBE growth in a same pre-processing chamber during epitaxial growth via program control. The combination of MOCVD and MBE crystal growth methods makes an in-situ growth of required solar cell structure available in different growing chambers, thus preventing sample surface oxidation and adsorption pollution and guaranteeing sample surface cleanliness.

### Embodiment 2

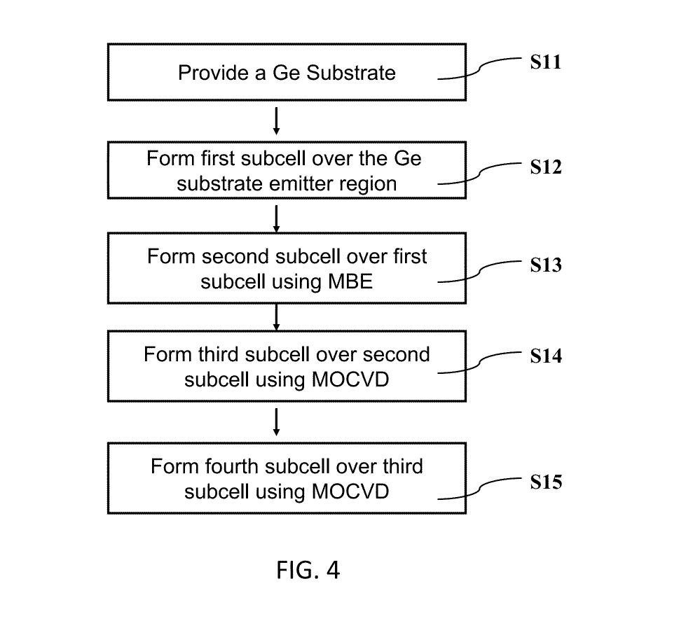

FIG. 4 discloses a process flow diagram of a fabrication method for four-junction solar cells.

Step S11: provide a Ge substrate. Select 140 μtm p-type Ge substrate 101 with doping concentration of 2×10¹⁷cm⁻³-5×10¹⁷cm⁻³.

Step S12: select the Ge substrate as the base to form a first subcell 100. In the MOCVD growing chamber, form an n-type GaAs with doping concentration of 2×10¹⁸cm⁻³ and thickness of 100 nm over the substrate 101 surface via epitaxial growth to serve as the first subcell emitter region 102. Form an InGaP material layer with thickness of 25 nm and doping concentration of 1×10¹⁸cm⁻³ over the n-type GaAs layer 102 via epitaxial growth to serve as a window layer 102. Select the p-type Ge substrate as the base to constitute a first subcell.

In the MOCVD growing chamber, form a high-doped p++/n++-GaAs tunnel junction 601 with thickness of 50 nm and doping concentration as high as 2×10¹⁹ cm⁻³ over the first subcell.

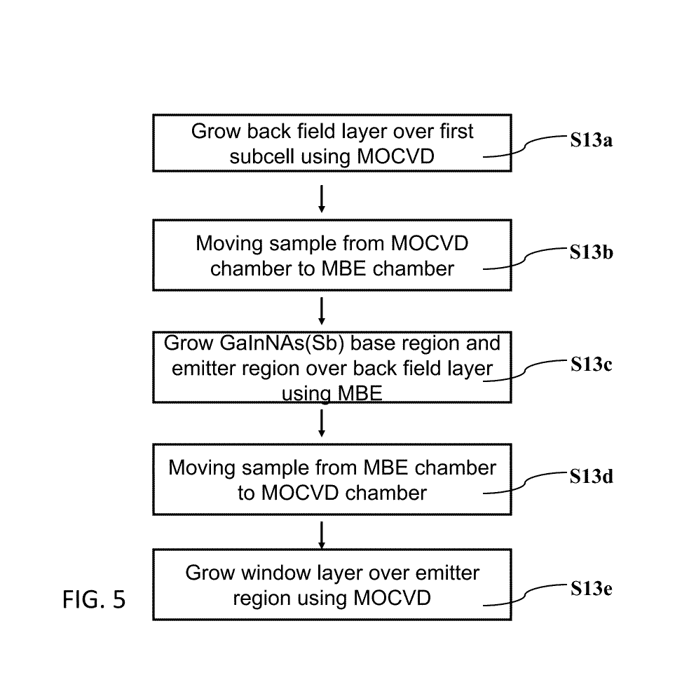

Step S13: form a GaInNAs(Sb) second subcell 200 over the tunnel junction 601. Referring to FIG. 5, it comprises Step S13a-S13e. S13a: In the MOCVD growing chamber 810, grow a p-type InGaP with thickness of 50 nm and doping concentration about 1×10¹⁸ cm⁻³ as the back surface field layer 201 over the tunnel junction 601. S13b: samples after growth, via the pre-processing chamber 830 and the vacuum channel 840, are transmitted to the MBE growing chamber 820. S13c: In the MBE growing chamber 820, form a Ga_{0.92}In_{0.08}N_{0.02}As_{0.97}Sb_{0.01} second subcell over the back surface field layer 201. Preferably, thickness of the base 202 is 3000 nm and doping concentration is 5×10¹⁷cm⁻³; the emitter region 203 is 200 nm thick with doping concentration of 2×10¹⁸cm⁻³. S13d: samples after growth, via the pre-processing chamber 830 and the vacuum channel 840, are transmitted back to the MOCVD growing chamber. S13e: In the MOCVD growing chamber, form an n-type InGaP window layer 204 with thickness of 25 nm and doping concentration about 1×10¹⁸cm⁻³ over the emitter region 203.

In the MOCVD growing chamber, grow a high-doped p++/n++-GaAs tunnel junction 602 with thickness of 50 nm and doping concentration as high as 2×10¹⁹ cm⁻³ over the second subcell.

Step S14: form a third subcell 300 over the second subcell via MOCVD.

In the MOCVD growing chamber, grow a p+-InGaP material layer with thickness of 50 nm and doping concentration of 1-2×10¹⁸ cm⁻³ over the tunnel junction 602 to serve as the back surface field layer 301; grow an n-type GaAs material layer with thickness of 2 μm and doping concentration of 1-5×10¹⁷ cm⁻³ over the back surface field layer 301 to serve as second subcell base 302; grow an n+-Ga(In)As material layer with thickness of 100 nm and doping concentration about 2×10¹⁸ cm⁻³ over the base 302 to serve as the emitter region 303; form an n-type InGaP window layer 304 with thickness of 25 nm and doping concentration about 1×10¹⁸ cm⁻³ over the emitter region 303.

In the MOCVD growing chamber, grow a high-doped p++/n++-InGaP tunnel junction 603 with thickness of 50 nm and doping concentration as high as 2×10¹⁹ cm⁻³ over the third subcell.

Step S15: form a fourth subcell 400 over the third subcell via MOCVD. In the MOCVD growing chamber, form a p-AlGaInP material layer with thickness of 100 nm and doping concentration of 1-2×10¹⁸ cm⁻³ via epitaxial growth over the tunnel junction 603 to serve as the back surface field layer 401; grow a p+-GaInP material layer with thickness of 1000 nm and doping concentration of 5×10¹⁷ cm⁻³ over the back surface field layer 401 to serve as the base 402; grow an n+-GaInP material layer with thickness of 100 nm and doping concentration of 2×10¹⁸ cm⁻³ over the base 402 to serve as the emitter region 403; form an n-type AlGaInP window layer 504 with thickness of 25 nm and doping concentration about 1×10¹⁸ cm⁻³ over the emitter region 403.

In the MOCVD growing chamber, grow a high-doped n++-GaAs material layer with thickness of 500 nm and concentration of 1×10¹⁹ cm⁻³ on the top of the fourth cell as the cap layer 700.

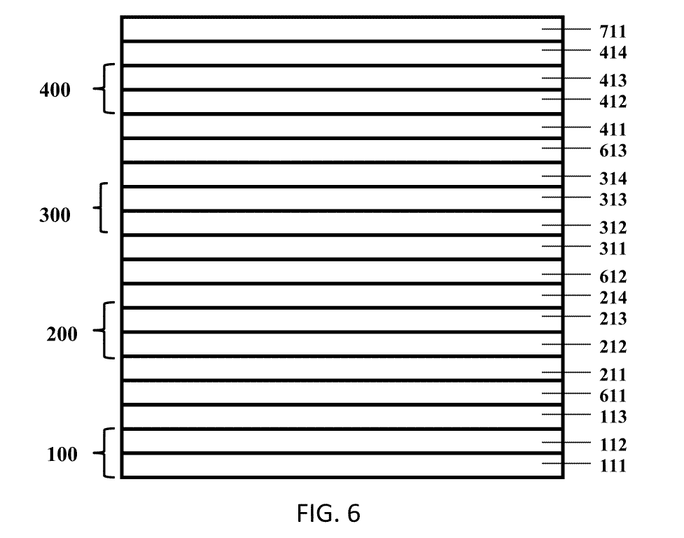

Lastly, take latter processes as AR coating evaporation on sample surface and metal electrode preparation to complete the required solar cell. Referring to FIG. 6 for the structural section view.

### Embodiment 3

A fabrication method for high-effective five junction solar cells, comprising the following steps:

Step S21: provide a Ge substrate. Select 140 μm p-type Ge substrate 111 with doping concentration of 2×10¹⁷cm⁻³-5×10¹⁷cm⁻³.

Step S22: select the Ge substrate as the base to form a first subcell 110. In the MOCVD growing chamber, form an n-type GaAs material layer with doping concentration of 2×10¹⁸ cm⁻³ and thickness of 100 nm over the substrate 111 surface via epitaxial growth to serve as the first subcell emitter region 112. Form an InGaP material layer with thickness of 25 nm and doping concentration of 1×10¹⁸ cm⁻³ over the n-type GaAs layer 112 via epitaxial growth to serve as a window layer 113. Select the p-type Ge substrate as the base to constitute a first subcell.

In the MOCVD growing chamber, form a high-doped p++/n++-GaAs tunnel junction 611 with thickness of 50 nm and doping concentration as high as 2×10¹⁹ cm⁻³ over the first subcell.

Step S23: form a GaInNAs(Sb) second subcell 210 over the tunnel junction 611. In the MOCVD growing chamber 810, grow a p-type InGaP with thickness of 50 nm and doping concentration about 1×10¹⁸ cm⁻³ as the back surface field layer 211 over the tunnel junction 611. Samples after growth, via the pre-processing chamber 830 and the vacuum channel 840, are transmitted to the MBE growing chamber 820. In the MBE growing chamber 820, form a Ga_{0.92}In_{0.08}N_{0.02}As_{0.97}Sb_{0.01} second subcell over the back surface field layer 211. Preferably, thickness of the base 212 is 3000 nm and doping concentration is 5×10¹⁷ cm⁻³; the emitter region 213 is 200 nm thick with doping concentration of 2×10¹⁸ cm⁻³. Samples after growth, via the pre-processing chamber 830 and the vacuum channel 840, are transmitted back to the MOCVD growing chamber. In the MOCVD growing chamber, form an n-type InGaP window layer 214 with thickness of 25 nm and doping concentration about 1×10¹⁸ cm⁻³ over the emitter region 213.

In the MOCVD growing chamber, grow a high-doped p++/n++-GaAs tunnel junction 612 with thickness of 50 nm and doping concentration as high as 2×10¹⁹ cm⁻³ over the second subcell.

Step S24: form a third subcell 310 over the second subcell via MOCVD. In the MOCVD growing chamber, grow a p+-InGaP material layer with thickness of 50 nm and doping concentration of 1-2×10¹⁸ cm⁻³ over the tunnel junction 612 to serve as the back surface field layer 311; grow an n-type Ga(In)As material layer with thickness of 2 μm and doping concentration of 1-5×10¹⁷ cm⁻³ over the back surface field layer 301 to serve as the base 312; grow an n+-Ga(In)As material layer with thickness of 100 nm and doping concentration about 2×10¹⁸ cm⁻³ over the base 312 to serve as the emitter region 313; form an n-type InGaP window layer 314 with thickness of 25 nm and doping concentration about 1×10¹⁸ cm⁻³ over the emitter region 313.

In the MOCVD growing chamber, grow a high-doped p++/n++-InGaP tunnel junction 613 with thickness of 50 nm and doping concentration as high as 2×10¹⁹ cm⁻³ over the third subcell.

Step S25: form a fourth subcell 400 over the third subcell via MOCVD. In the MOCVD growing chamber, form a p-AlGaInP material layer with thickness of 100 nm and doping concentration of 1-2×10¹⁸ cm⁻³ via epitaxial growth over the tunnel junction 613 to serve as the back surface field layer 411; grow a p+-AlxGa1-xAs material layer with thickness of 1000 nm and doping concentration of 5×10¹⁷ cm⁻³ over the back surface field layer 411 to serve as the base 402; grow an n+-AlxGa1-xAs material layer with thickness of 100 nm and doping concentration of 2×10¹⁸ cm⁻³ over the base 402 to serve as the emitter region 413; form an n-type AlGaInP window layer 414 with thickness of 25 nm and doping concentration about 1×10¹⁸ cm⁻³ over the emitter region 413.

In the MOCVD growing chamber, grow a high-doped p++/n++-AlGaAs tunnel junction 614 with thickness of 50 nm and doping concentration as high as 2×10¹⁹ cm⁻³ over the fourth and fifth subcells.

Step S26: form a fifth subcell 500 over the fourth subcell via MOCVD. In the MOCVD growing chamber, form a p-AlGaAs material layer with thickness of 100 nm and doping concentration of 1-2×10¹⁸ cm³ via epitaxial growth over the tunnel junction 614 to serve as the back surface field layer 511; form a p+-AlxGayIn1-x-yP material layer with thickness of 500 nm and doping concentration of 1-5×10¹⁷cm⁻³ over the back surface field layer 511 via epitaxial growth to serve as the base 512; grow an n+-AlxGayIn1-x-yP material layer with thickness of 50 nm and doping concentration about 2×10¹⁸ cm⁻³ over the base 512 to serve as the emitter region 513; form an n-type AlGaAs window layer 903 with thickness of 25 nm and doping concentration about 1×10¹⁸ cm⁻³ over the emitter region 513.

In the MOCVD growing chamber, grow a high-doped n++-GaAs material layer with thickness of 500 nm and concentration of 1×10¹⁹ cm⁻³ on the top of the fourth cell as the cap layer 710.

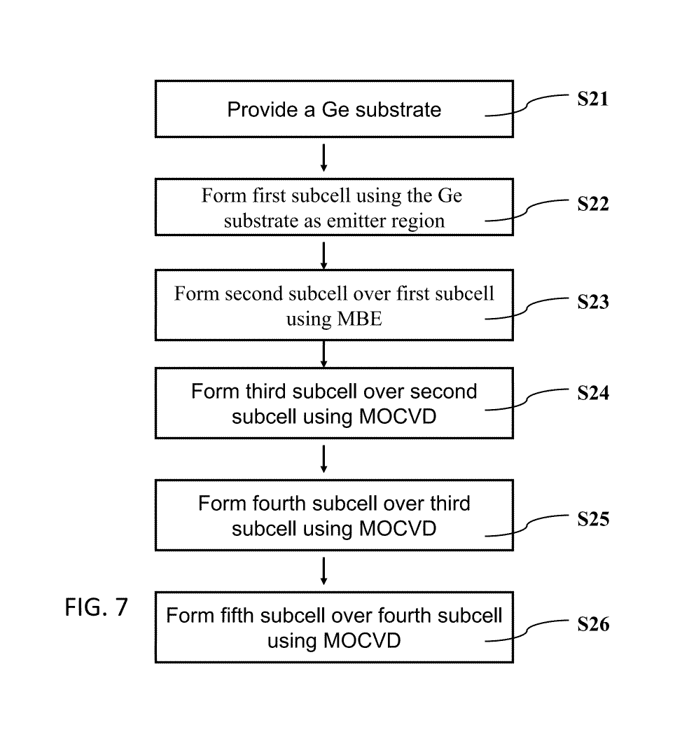

Lastly, take latter processes as AR coating evaporation on sample surface and metal electrode preparation to complete the required solar cell. Referring to FIG. 7 for the structural section view.

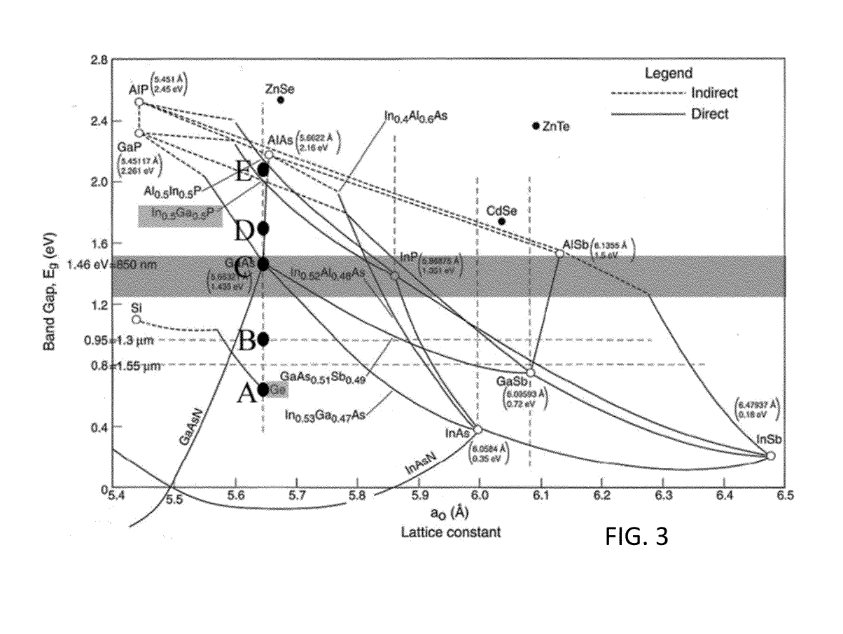

According to the embodiment, a Ge/GaInNAs(Sb)/InGaAs/AlGaAs/AlGaInP five junction solar cell is provided and the band gap distribution is as shown in FIG. 3. In comparison with the four junction solar cell, the five-junction solar cell refines the absorption spectrum to facilitate current matching, wider spectrum absorption scope and higher efficiency.

The solar cells can be used in a solar energy generation system, which may include a number of the solar cells according to embodiments disclosed here.

1. A fabrication method for multi junction solar cells, comprising:
(1) providing a Ge substrate for semiconductor epitaxial growth;
(2) growing an emitter region over the Ge substrate to form a first subcell with a first band gap, wherein the Ge substrate forms a base region;
(3) forming a second subcell with a second band gap larger than the first band gap and lattice matched with the first subcell over the first subcell via MBE;
(4) forming a third subcell with a third band gap larger than the second band gap and lattice matched with the first and second subcells over the second subcell via MOCVD; and
(5) forming a fourth subcell with a fourth band gap larger than the third band gap and lattice matched with the first, second, and third subcells over the third subcell via MOCVD.

2. The method of claim 1, wherein the second subcell is a GaInNAs(Sb) cell.

3. The method of claim 2, wherein for the second subcell the method further comprising:
forming a back surface field layer via MOCVD over the first subcell;
forming a GaInNAs(Sb) base and an emitter region over the back surface field layer via MBE; and
forming a window layer over the emitter region via MOCVD, thereby forming the second subcell.

4. The method of claim 2, wherein the first subcell has a band gap from 0.65 to 0.70 eV, the second subcell has a band gap from 0.95 to 1.05 eV, the third subcell has a band gap from 1.35 to 1.45 eV, and the fourth subcell has a band gap from 1.86 to 1.95 eV.

5. The method of claim 4, wherein the third subcell is a Ga(In)As cell and the fourth subcell is a GaInP cell.

6. The method of claim 2, further comprising step (6) including: forming a fifth subcell with a fifth band gap larger than the fourth band gap and lattice matched with the first, second, third, and fourth subcells via MOCVD over the fourth subcell, thereby forming a five junction solar cell.

7. The method of claim 6, wherein the first subcell has a band gap from 0.67 to 0.70 eV, the second subcell has a band gap from 0.95 to 1.05 eV, the third subcell has a band gap from 1.40-1.42 eV, the fourth subcell has a band gap from 1.60 to 1.70 eV, and the fifth subcell has a band gap from 1.90 to 2.10 eV.

8. The method of claim 7, wherein the third subcell is a Ga(In)As cell, the fourth subcell is an AlGaAs cell, and the fifth subcell is an AlGaInP cell.

9. The method of claim 8, wherein the fifth subcell is quaternary component AlₓGa_{y}In_{1-x-y}P. Through adjustment of components x and y, a lattice matching is available with all other subcells if the band gap is satisfied.

10. An epitaxial growth system configured to epitaxially grow multi junction solar cells over a Ge substrate, wherein the system is configured to:
grow an emitter region over the Ge substrate to form a first subcell with a first band gap, wherein the Ge substrate forms a base region;
form a second subcell with a second band gap larger than the first band gap and lattice matched with the first subcell over the first subcell via MBE;
form a third subcell with a third band gap larger than the second band gap and lattice matched with the first and second subcells over the second subcell via MOCVD; and
form a fourth subcell with a fourth band gap larger than the third band gap and lattice matched with the first, second, and third subcells over the third subcell via MOCVD,
the system comprising:
an MOCVD reaction chamber;
an MBE reaction chamber; and
a pre-processing chamber,
wherein the MOCVD reaction chamber and the MBE reaction chamber share the pre-processing chamber and are coupled via a channel, and
wherein a transfer device is provided inside the channel.

11. The system of claim 10, wherein the channel is a vacuum channel with vacuum level maintained below 1×10⁻⁶ Pa.

12. A solar energy generation system comprising a plurality of multi junction solar cells, each solar cell comprising:
(1) a Ge substrate for semiconductor epitaxial growth;
(2) an emitter region grown over the Ge substrate to form a first subcell with a first band gap, wherein the Ge substrate forms a base region;
(3) a second subcell with a second band gap larger than the first band gap and lattice matched with the first subcell, grown over the first subcell via MBE;
(4) a third subcell with a third band gap larger than the second band gap and lattice matched with the first and second subcells, grown over the second subcell via MOCVD; and
(5) a fourth subcell with a fourth band gap larger than the third band gap and lattice matched with the first, second, and third subcells, grown over the third subcell via MOCVD.

13. The system of claim 12, wherein the second subcell is a GaInNAs(Sb) cell.

14. The system of claim 13, wherein for the second subcell is formed by:
forming a back surface field layer via MOCVD over the first subcell;
forming a GaInNAs(Sb) base and an emitter region over the back surface field layer via MBE; and
forming a window layer over the emitter region via MOCVD, thereby forming the second subcell.

15. The system of claim 13, wherein the first subcell has a band gap from 0.65 to 0.70 eV, the second subcell has a band gap from 0.95 to 1.05 eV, the third subcell has a band gap from 1.35 to 1.45 eV, and the fourth subcell has a band gap from 1.86 to 1.95 eV.

16. The system of claim 15, wherein the third subcell is a Ga(In)As cell and the fourth subcell is a GaInP cell.

17. The system of claim 13, wherein each solar cell is a five junction solar cell formed by: forming a fifth subcell with a fifth band gap larger than the fourth band gap and lattice matched with the first, second, third, and fourth subcells via MOCVD over the fourth subcell.

18. The system of claim 17, wherein the first subcell has a band gap from 0.67 to 0.70 eV, the second subcell has a band gap from 0.95 to 1.05 eV, the third subcell has a band gap from 1.40-1.42 eV, the fourth subcell has a band gap from 1.60 to 1.70 eV, and the fifth subcell has a band gap from 1.90 to 2.10 eV.

19. The system of claim 18, wherein the third subcell is a Ga(In)As cell, the fourth subcell is an AlGaAs cell, and the fifth subcell is an AlGaInP cell.

20. The system of claim 19, wherein the fifth subcell is quaternary component AlₓGa_{y}In_{1-x-y}P. Through adjustment of components x and y, a lattice matching is available with all other subcells if the band gap is satisfied.
